(19) United States
(12) Patent Application Publication
(10) Pub. No.: US 2026/0066028 A1
(43) Pub. Date: Mar. 5, 2026

(54) SHADOW LOGIC ON OUTPUT, AT SPEED TEST (MEMORY BYPASS) ARCHITECTURE FOR MEMORIES WITHOUT INPUT DATA

(71) Applicant: STMicroelectronics International N.V., Geneva (CH)

(72) Inventors: Praveen Kumar VERMA, Greater Noida (IN); Harsh RAWAT, Faridabad (IN); Promod KUMAR, Greater Noida (IN); Eric FAEHN, Saint Barthelemy De Sechilienne (FR); Ludovice GOUALOU, Le Cheylas (FR)

(73) Assignee: STMicroelectronics International N.V., Geneva (CH)

(21) Appl. No.: 19/302,859

(22) Filed: Aug. 18, 2025

Related U.S. Application Data
(60) Provisional application No. 63/687,901, filed on Aug. 28, 2024.

(51) Int. Cl. G11C 29/44

(52) U.S. Cl. CPC G11C 29/44

(57) ABSTRACT

Disclosed herein is a self-timed memory circuit with a bypass mode for testing output shadow logic. The circuit is applicable to various memory types, including ROM, HistoRAM, and TCAM. In normal operation, the memory array outputs data through sense amplifiers and latches, controlled by self-timing circuitry. The output then passes through shadow logic for additional processing. The bypass mode allows direct testing of the shadow logic by inputting test patterns (address bits or search keys) that bypass the memory array. These test signals use the same self-timing mechanisms as normal operations, providing for accurate timing representation. This approach enhances fault coverage for shadow logic, enabling detection of transient faults and at-speed errors that might be missed by conventional static testing.

### RELATED APPLICATION

This application claims priority to U.S. Provisional Application for Patent No. 63/687,901, filed Aug. 28, 2024, the contents of which are incorporated by reference in their entirety.

### TECHNICAL FIELD

This disclosure relates generally to the field of integrated circuit design and testing, with a specific focus on memory circuits and their associated logic. More particularly, this disclosure pertains to methods and systems for testing shadow logic in various types of memory architectures, including but not limited to Read-Only Memory (ROM), Histogram Random Access Memory (HistoRAM), and Ternary Content-Addressable Memory (TCAM).

### BACKGROUND

Reference is made to FIG. 1 which shows a block diagram of a self-timed memory circuit 10. The memory circuit 10 includes a memory array 12 configured to store user data, a read/write row decoder circuit 14, and data input/output circuits 16. The memory array 12 includes a plurality of memory cells arranged in a matrix of rows and columns. During write operations, the read/write decoder circuit 14 decodes an input address and asserts a word line coupled to a row of memory cells in the memory array 12. Data input to the input/output circuits 16 is written by write circuits for storage in the row of memory cells through write bit lines each connected to a column of memory cells in the memory array 12.

It is critical that the write circuits of the input/output circuits 16 be actuated by word line signals for a sufficient amount of time to ensure that the data is successfully written to the memory cells in the accessed row of the memory array 12. The memory circuit 10 includes self time circuitry formed by a dummy read/write decoder (DRD/DWD) 18, one or more dummy columns 20 of memory cells in the array 12, one or more dummy rows 22 of memory cells in the array 12, and a dummy input/output (DIO) circuit 24.

At the start of a write operation, when the read/write row decoder circuit 14 asserts the word line in response to decoding the address, the dummy decoder (DRD/DWD) 18 asserts a dummy write word line coupled to the row of memory cells in the dummy row 22 and further to at least one memory cell in the column of memory cells of the dummy column 20. The dummy input/output (DIO) circuit 24 writes data to the memory cell(s) of the dummy column 20 and senses completion of the write operation. In response that sensed completion, the control circuit 26 of the memory can control the read/write row decoder circuit 14 to timely terminate assertion of the word line signal on the word line.

For the write operation, the dummy row 22 is designed and positioned to track (e.g., emulate) the worst-case delay for each SRAM cell in the selected row of the memory array 12 to accept a new data value during a write operation. This accounts for the time it takes for an SRAM cell in the memory array 12 to store the incoming value. The dummy column 20 tracks the worst-case delay associated with establishing the correct data value onto the bit lines, ensuring that the targeted SRAM cell in the memory array 12 stores the proper data value.

During read operations, the read/write row decoder circuit 18 decodes an input address and asserts a read word line coupled to a row of memory cells in the memory array 12. Data stored in the memory cells at that row is output to read bit lines each connected to a column of memory cells in the core memory area 12 and sensed by read circuits of the input/output circuits 16 for output. It is critical that the sensing operation performed by the read circuits of the input/output circuits 16 be actuated no earlier than when the read data is made available on the read bit lines to ensure that the data is successfully read from the memory cells in the accessed row of the core memory area 12. The memory circuit 10 includes read self-time circuitry formed by a dummy read/write decoder (DRD/DWD) 18, one or more dummy columns 20 of memory cells in the array 12, one or more dummy rows 22 of memory cells in the array 12, and a dummy read input/output (DIO) circuit 24. At the start of the read operation, when the read/write row decoder circuit 14 asserts the read word line in response to decoding the address, the dummy read/write decoder (DRD/DWD) 18 asserts a dummy read word line coupled to the row of memory cells in the dummy row 22 and further to at least one memory cell in the column of memory cells of the dummy column 20. The dummy read input/output (DIO) circuit 24 senses availability of read data from the memory cell(s) of the dummy column 20. In response that sensed availability, the control circuit 26 of the memory can time control the actuation of the read sense circuits of the input/output circuits 16 to sense the read data on the read bit line.

For the read operation, the dummy row 22 is designed and positioned to track (e.g., emulate) the worst-case delay for each SRAM cell in the selected row of the memory array 12 to reflect its state change onto its corresponding bit lines during a read operation. In addition, the dummy column 20 is designed and positioned to track (e.g., emulate) the worst-case bit line delay during a read operation, ensuring that the read circuits are timely actuated to successfully sense the read data value.

After fabrication, or upon startup, it is desired to be able to test the functionality of the memory circuit 10.

To perform a first kind of such testing, a BIST controller 34 is shown as shifting an n bit data word D[0], . . . , D[n−1] into the input/output circuits 16 through multiplexers 36, and after being operated upon by the memory circuit 10 for testing, the result is shifted out of the input/output circuits 16 as an n-bit data word Q[0], . . . , Q[n−1] and back to the BIST controller 34. This provides for testing of the memory array 12 itself.

To perform a second kind of testing in which the shadow logic (both input shadow logic 30 and output shadow logic 32) is tested on its own, an n-bit data word D[0], . . . , D[n−1] is shifted out of the input shadow logic 30 and into the output shadow logic 32 through multiplexers 30. If the output from the output shadow logic 32 is as expected (which is determined by test circuit 40), then it can be understood that the shadow logic is operating as expected; otherwise, it can be understood that the shadow logic is not operating as expected.

The issue with this testing regime for the shadow logic is that in actual operation, data would be shifted from the input shadow logic 30 into the memory array 12 through the multiplexers 36 and the input/output circuits 16, and then out from the memory array 12 through the input/output circuits 16 and the multiplexers 38 into the output shadow logic 32. This shifting through the memory array 12 necessarily involves delay, and this specific delay varies with process, voltage, and temperature. Due to this issue, the above type of existing testing regime for the shadow logic itself may be insufficient, as it may only uncover certain types of errors (e.g., stuck-at errors) while missing other types of errors (e.g., at-speed faults).

In order to address this issue, techniques of routing the output from the input shadow logic 30 through the input/output circuits 16 have been developed, and such designs are functional for SRAM memories. However, other types of memories exist, such as read only memory (ROM), Ternary Content Addressable Memory (TCAM), and HistoRAM. These memories lack data inputs. As such, these developed techniques are inapplicable to such memories and further development is necessary.

### SUMMARY

A memory circuit has a memory array, an output circuit coupled to the memory array, a self-timing circuit including a dummy decoder, a dummy memory element, and a dummy output circuit, a control circuit, an input latch within the control circuit for receiving input data, a multiplexer coupled to the output circuit, an output latch coupled to the multiplexer and clocked by an output of the dummy output circuit, and an output shadow logic coupled to the output latch. In a normal operation mode, the input data is used to access the memory array, and the output circuit provides output data from the accessed memory array to the multiplexer. In the normal operation mode, the multiplexer passes data from the output circuit to the latch, and in a bypass mode, activated by a bypass mode signal from the control circuit, the multiplexer passes the input data from the input latch to the output latch, bypassing the memory array.

The latch may be clocked by the output of the dummy output circuit in both the normal operation mode and the bypass mode.

The memory array may be a Read-Only Memory (ROM) array, and the input data may be address bits.

The memory array may be a Histogram Random Access Memory (HistoRAM) array, and the input data may be address bits.

The memory array may be a Ternary Content-Addressable Memory (TCAM) array, and the input data may be search key bits.

The output shadow logic may be configured to perform combinatorial logic operations on data received from the latch.

The memory circuit may have a test circuit coupled to an output of the output shadow logic, and in the bypass mode, the test circuit may verify proper operation of the output shadow logic.

The self-timing circuit may be configured to emulate a worst-case delay of the memory array in the normal operation mode.

The memory array may lack a data input.

The input data may be smaller in bit length than the output data.

A method of operating a memory circuit includes receiving input data at an input latch within a control circuit. In a normal operation mode, the method includes using the input data to access a memory array, providing output data from the accessed memory array to a multiplexer via an output circuit, passing the output data from the multiplexer to an output latch, and clocking the output latch with an output from a dummy output circuit of a self-timing circuit. In a bypass mode, the method includes activating a bypass mode signal from the control circuit, passing the input data from the input latch to the output latch via the multiplexer, bypassing the memory array, and clocking the output latch with the output from the dummy output circuit of the self-timing circuit. The method also includes processing data from the output latch with an output shadow logic.

The memory array may be a Read-Only Memory (ROM) array, and the input data may be address bits.

The memory array may be a Histogram Random Access Memory (HistoRAM) array, and the input data may be address bits.

The memory array may be a Ternary Content-Addressable Memory (TCAM) array, and the input data may be search key bits.

Processing data from the output latch may include performing combinatorial logic operations on the data.

The method may include, in the bypass mode, verifying proper operation of the output shadow logic using a test circuit coupled to an output of the output shadow logic.

The method may include emulating a worst-case delay of the memory array using the self-timing circuit.

### BRIEF DESCRIPTION OF THE DRAWINGS

FIG. 1 is a block diagram of a prior art self-timed memory circuit.

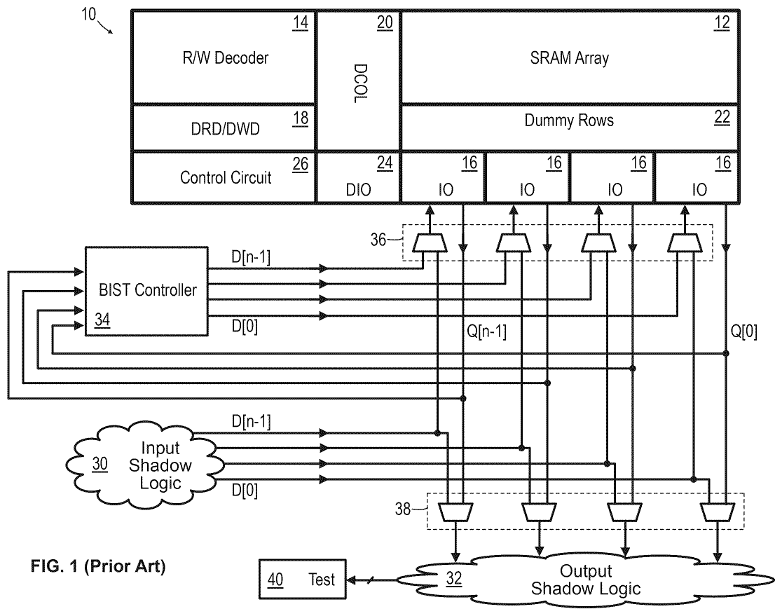

FIG. 2 is a block diagram of a self-timed memory circuit with shadow logic testing capabilities.

FIG. 3 is a block diagram of a self-timed ROM or HistoRAM memory circuit according to an embodiment of this disclosure.

FIG. 4 is a block diagram of a self-timed TCAM circuit according to another embodiment of this disclosure.

### DETAILED DESCRIPTION

The following disclosure enables a person skilled in the art to make and use the subject matter described herein. The general principles outlined in this disclosure can be applied to embodiments and applications other than those detailed above without departing from the spirit and scope of this disclosure. It is not intended to limit this disclosure to the embodiments shown, but to accord it the widest scope consistent with the principles and features disclosed or suggested herein.

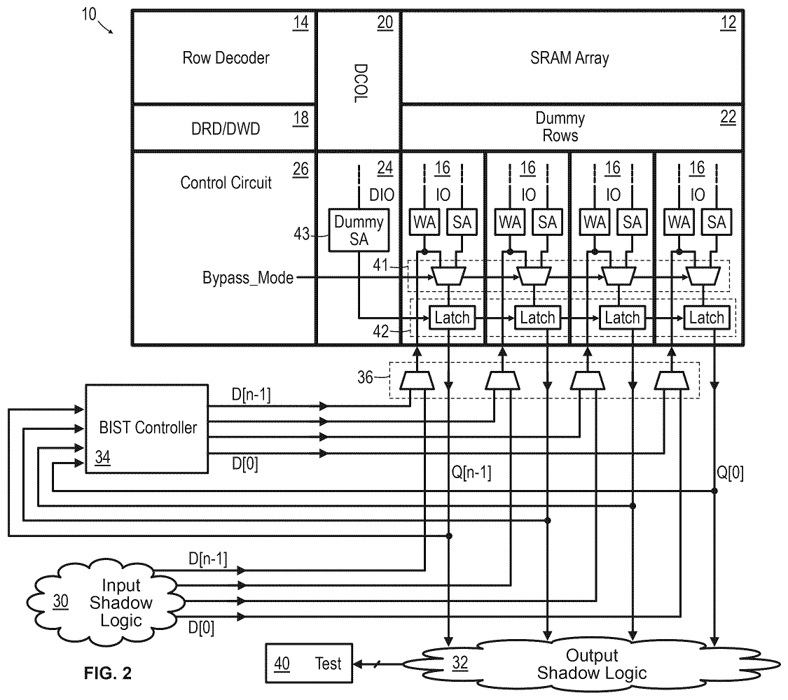

Refer now to FIG. 2, showing a technique for routing the output from the input shadow logic through the input/output circuits in a self-timed memory circuit with shadow logic testing capabilities. Here, to test the shadow logic (both input shadow logic 30 and output shadow logic 32) on their own, an n-bit data word D[0], . . . , D[n−1] is shifted out of the input shadow logic 30 and into the input/output circuits 16 through multiplexers 36, then back out through multiplexers 41 and latches 42 to the output shadow logic 32. So as to match the delay that would be present if the data were shifted through the memory array 12 itself, the latches 42 are clocked by the self-time operation previously described for the memory circuit 10, namely when the dummy sense amplifier 43 within the dummy input/output circuit 24 has output the result of the dummy read operation.

This design of FIG. 2 is functional for SRAM memories, but not for ROM, TCAM, and HistoRAM memories.

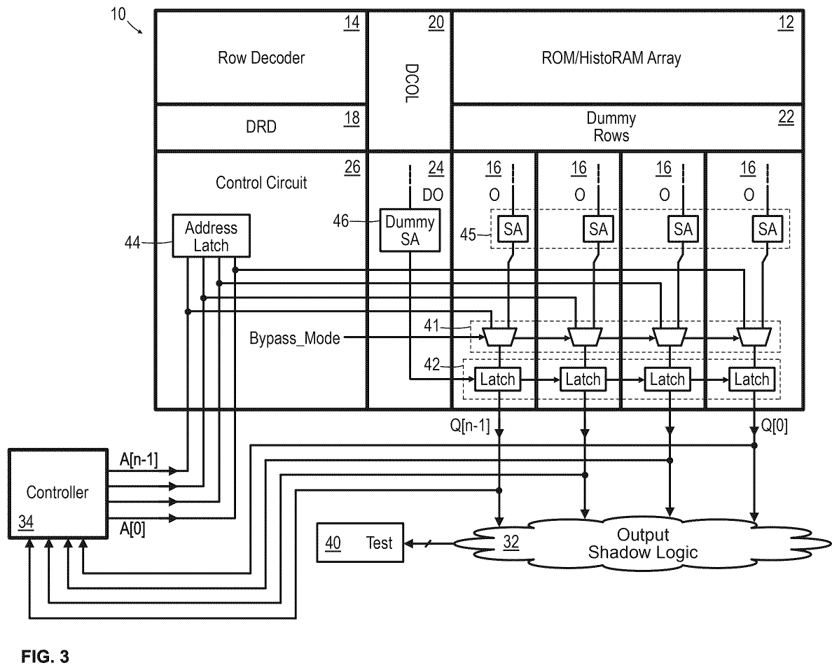

Refer now to FIG. 3, showing a block diagram of a self-timed ROM or HistoRAM memory circuit 10. By way of brief explanation, when a ROM receives an address, it responds by reading the corresponding data word at that address and outputting that data word. In contrast, when a HistoRAM receives an address, it responds by reading the data word stored at that address, internally incrementing its value, and writing the incremented value back to the same address, all within a single clock cycle.

First, the ROM embodiment is described. The memory circuit 10 includes a ROM array 12 to store fixed data, a row decoder circuit 14, and data output circuits 16. The ROM array 12 includes a plurality of memory cells arranged in a matrix of rows and columns.

A controller 34 outputs address bits A[0], . . . , A[n−1] to an address latch 44 within the control circuit 26. During read operations, the row decoder circuit 14 decodes the latched input address and asserts a word line coupled to a row of memory cells in the ROM array 12. Data stored in the memory cells at that row is output to bit lines each connected to a column of memory cells in the ROM array 12 and sensed by read circuits (e.g., sense amplifiers 45) of the output circuits 16 for output.

The sensing operation performed by the read sense circuits 45 of the output circuits 16 is to be actuated at the right time such that the data is successfully read from the memory cells in the accessed row of the ROM array 12. To that end, the memory circuit 10 includes self-time circuitry formed by a dummy read decoder (DRD) 18, one or more dummy columns 20, one or more dummy rows 22, and a dummy input/output (DIO) circuit 24.

At the start of the read operation, when the row decoder circuit 14 asserts the read word line in response to decoding the address, the dummy read decoder (DRD) 18 asserts a dummy read word line. The dummy input/output (DIO) circuit 24 senses availability of read data from the memory cell(s) of the dummy column 20. In response to that sensed availability, the control circuit 26 of the memory 10 can time control the actuation of the read sense circuits 45 of the output circuits 16 to sense the read data on the bit lines. The output of the read sense circuits 45 is passed through multiplexers 41 (when in a normal operating mode), through latches 42 (clocked by the result of the dummy read as output by dummy sense amplifier 46 within the dummy output circuit 24) to output shadow logic 32 as output bits Q[0], . . . , Q[n−1]. The output shadow logic 32 performs combinatorial logic operations on the data, before the final output is produced. A test circuit 40 is connected to the output of the output shadow logic 32.

To perform a test of the output shadow logic 32, the bypass mode signal Bypass_Mode is asserted by the control circuit 26, having the effect of causing the multiplexers 41 to output the address bits A[0], . . . , A[n−1] that were provided to the address latch 44 to the latches 42, which are clocked by the same self-time mechanism (e.g., the output of the dummy sense amplifier 46) described above. Thus, in this bypass mode, the address bits A[0], . . . , A[n−1] are output as output bits Q[0], . . . , Q[n−1] to the output shadow logic 32, which performs combinatorial logic operations on the data, before the final output is produced. A test circuit 40 is connected to the output of the output shadow logic 32 and verifies that the output from the output shadow logic 32 is as expected. If the output from the shadow logic is as expected, it can be inferred that the shadow logic 32 itself is operating properly. Conversely, if the output from the shadow logic is not as expected, it can be inferred that the shadow logic 32 itself is not operating properly.

In the case where the array 12 is a HistoRAM array instead of a ROM array, the operation and testing procedure are slightly different. A HistoRAM, or Histogram RAM, is designed to increment the value stored at a given address each time that address is accessed. When the controller 34 outputs an address A[0], . . . , A[n−1] to the address latch 44, the HistoRAM array 12 reads the current value at that address, increments it, and writes the new value back to the same address, all within a single clock cycle. The incremented value is then output through the sense amplifiers 45, multiplexers 41, and latches 42 to the output shadow logic 32. The self-timing mechanism remains crucial in this operation to ensure proper read, increment, and write-back timing.

For testing the output shadow logic 32 in the HistoRAM configuration, the bypass mode operates similarly to the ROM version. When the Bypass_Mode signal is asserted, the address bits A[0], . . . , A[n−1] bypass the HistoRAM array and are directly sent through the multiplexers 41 and latches 42 to the output shadow logic 32. This allows for isolated testing of the shadow logic, independent of the HistoRAM's increment functionality. The test circuit 40 can then verify if the output shadow logic 32 correctly processes these bypassed address bits, allowing for fault detection specifically within the shadow logic circuitry, separate from the HistoRAM array operations.

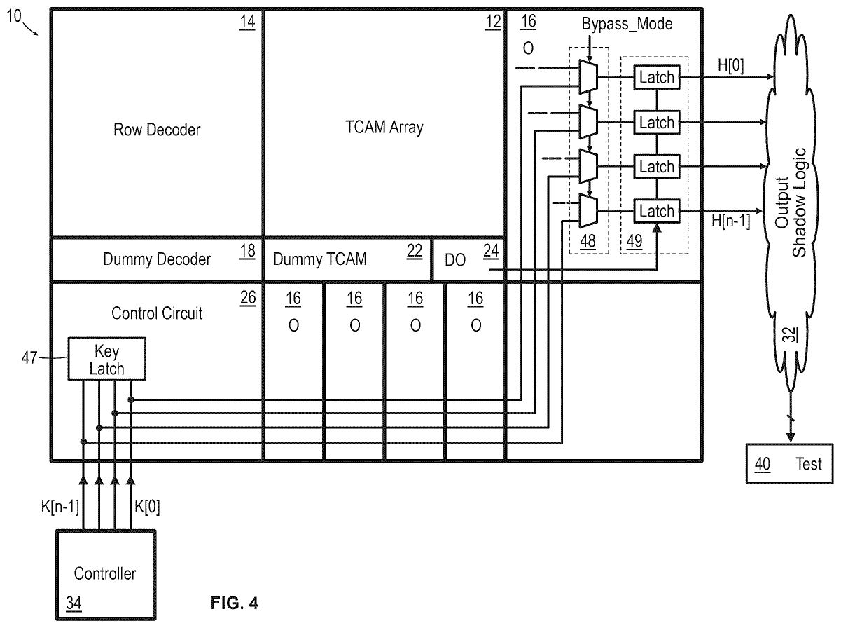

Refer now to FIG. 4, showing a block diagram of a self-timed Ternary Content Addressable Memory (TCAM) circuit 10. The TCAM circuit 10 includes a TCAM array 12, a row decoder 14, output circuits 16, a dummy decoder 18, a dummy TCAM row 22, a dummy output 24, and a control circuit 26. The control circuit 26 contains a key latch 47 that receives a search key K[0], . . . , K[n−1].

In normal operation, the TCAM array 12 compares the search key against its stored contents to find matching entries. The row decoder 14 activates all rows in the TCAM array 12 for parallel comparison. The sensing operation performed by the output circuits 16 needs to be actuated at the right time to ensure successful matching. To achieve this, the circuit includes self-time circuitry formed by the dummy decoder 18, dummy TCAM row 22, and dummy output 24. When a search operation begins, the dummy decoder 18 activates the dummy TCAM row 22. The dummy output 24 senses the completion of the dummy search operation, providing a timing signal to control the main TCAM array output.

The output circuits 16 include sense amplifiers (not shown) that detect matches in each column of the TCAM array 12. The results of these matches, represented as hit signals H[0], . . . , H[n−1], are then passed through multiplexers 48 and latches 49. The latches 49 are clocked by the self-time operation, specifically by the output of the dummy output 24. This ensures that the hit signals are captured at the appropriate time.

The hit signals H[0], . . . , H[n−1] are then fed into the output shadow logic 32. This shadow logic performs additional processing on the hit signals, such as priority encoding or error checking, before the final output is produced.

To perform a test of the output shadow logic 32 independently of the TCAM array 12, a bypass mode is implemented. When the bypass mode signal is asserted by the control circuit 26, the multiplexers 48 are switched to bypass the TCAM array 12 and its associated sense amplifiers. Instead, the search key bits K[0], . . . , K[n−1] from the key latch 47 are passed directly through the multiplexers 48 to the latches 49. These latches are still clocked by the same self time mechanism (i.e., the output of the dummy output 24) as in normal operation.

In this bypass mode, the search key bits K[0], . . . , K[n−1] effectively serve as simulated hit signals and are output as H[0], . . . , H[n−1] to the output shadow logic 32. The shadow logic then performs its usual combinatorial logic operations on these simulated hit signals. The test circuit 40, connected to the output of the shadow logic 32, verifies that the output from the shadow logic is as expected based on the known input (the search key bits).

If the output from the shadow logic matches the expected result for the given input, it can be inferred that the shadow logic 32 itself is operating properly. Conversely, if the output doesn't match expectations, it indicates a potential issue within the shadow logic circuitry. This bypass mode thus allows for isolated testing of the shadow logic, separate from the TCAM array's search operations, enabling efficient fault detection and diagnosis.

By implementing a bypass mode, disclosed embodiments allow for the direct input of test patterns (such as address bits or search keys) to the shadow logic, effectively simulating the output of the memory array. This bypass path incorporates the same self-timing mechanisms used in normal memory operations, including dummy decoders, dummy rows, and dummy output circuits. This ensures that the test signals propagate through the system with delays that accurately reflect those experienced during actual memory access, including variations due to Process, Voltage, and Temperature (PVT) factors.

This approach significantly enhances the fault coverage for shadow logic, addressing a gap in traditional memory testing methodologies. Specifically, it allows for the detection of transient faults and at-speed errors that might be missed by conventional static testing methods. The is particularly valuable for testing shadow logic that generates output patterns based on memory addresses and other input pins, as these patterns can now be directly simulated and verified.

Furthermore, the flexibility of this testing method makes it applicable across a wide range of memory types. Whether dealing with the simple read operations of a ROM, the read modify-write cycles of a HistoRAM, or the complex search operations of a TCAM, the disclosed embodiments with the bypass mode can accurately emulate the timing and behavior of each memory type. In fact, this testing method is applicable to any memory array which lacks a data input that receives data to be written to the memory array, or for which the input data to the memory is smaller in bit length than the output data from the memory.

Finally, it is evident that modifications and variations can be made to what has been described and illustrated herein without departing from the scope of this disclosure.

Although this disclosure has been described with a limited number of embodiments, those skilled in the art, having the benefit of this disclosure, can envision other embodiments that do not deviate from the disclosed scope. Furthermore, skilled persons can envision embodiments that represent various combinations of the embodiments disclosed herein made in various ways.

1. A memory circuit, comprising:
a memory array;
an output circuit coupled to the memory array;
a self-timing circuit including a dummy decoder, a dummy memory element, and a dummy output circuit;
a control circuit;
an input latch within the control circuit for receiving input data;
a multiplexer coupled to the output circuit;
an output latch coupled to the multiplexer and clocked by an output of the dummy output circuit; and
an output shadow logic coupled to the output latch;
wherein in a normal operation mode, the input data is used to access the memory array, and the output circuit provides output data from the accessed memory array to the multiplexer; and
wherein in the normal operation mode, the multiplexer passes data from the output circuit to the latch, and wherein in a bypass mode, activated by a bypass mode signal from the control circuit, the multiplexer passes the input data from the input latch to the output latch, bypassing the memory array.

2. The memory circuit of claim 1, wherein the latch is clocked by the output of the dummy output circuit in both the normal operation mode and the bypass mode.

3. The memory circuit of claim 1, wherein the memory array is a Read-Only Memory (ROM) array, and wherein the input data comprise address bits.

4. The memory circuit of claim 1, wherein the memory array is a Histogram Random Access Memory (HistoRAM) array, and wherein the input data comprise address bits.

5. The memory circuit of claim 1, wherein the memory array is a Ternary Content Addressable Memory (TCAM) array, and wherein the input data comprises search key bits.

6. The memory circuit of claim 1, wherein the output shadow logic is configured to perform combinatorial logic operations on data received from the latch.

7. The memory circuit of claim 1, further comprising a test circuit coupled to an output of the output shadow logic, and wherein in the bypass mode, the test circuit verifies proper operation of the output shadow logic.

8. The memory circuit of claim 1, wherein the self-timing circuit is configured to emulate a worst-case delay of the memory array in the normal operation mode.

9. The memory circuit of claim 1, wherein the memory array lacks a data input.

10. The memory circuit of claim 1, wherein the input data is smaller in bit length than the output data.

11. A method of operating a memory circuit, comprising:
receiving input data at an input latch within a control circuit;
in a normal operation mode:
using the input data to access a memory array;
providing output data from the accessed memory array to a multiplexer via an output circuit;
passing the output data from the multiplexer to an output latch; and
clocking the output latch with an output from a dummy output circuit of a self timing circuit;
in a bypass mode:
activating a bypass mode signal from the control circuit;
passing the input data from the input latch to the output latch via the multiplexer, bypassing the memory array; and
clocking the output latch with the output from the dummy output circuit of the self-timing circuit; and
processing data from the output latch with an output shadow logic.

12. The method of claim 11, wherein the memory array is a Read-Only Memory (ROM) array, and wherein the input data comprises address bits.

13. The method of claim 11, wherein the memory array is a Histogram Random Access Memory (HistoRAM) array, and wherein the input data comprises address bits.

14. The method of claim 11, wherein the memory array is a Ternary Content Addressable Memory (TCAM) array, and wherein the input data comprises search key bits.

15. The method of claim 11, wherein processing data from the output latch comprises performing combinatorial logic operations on the data.

16. The method of claim 11, further comprising in the bypass mode, verifying proper operation of the output shadow logic using a test circuit coupled to an output of the output shadow logic.

17. The method of claim 11, further comprising emulating a worst-case delay of the memory array using the self-timing circuit.

18. A memory circuit, comprising:
a memory array configured to store data;
output circuitry coupled to the memory array and configured to output data from the memory array;
shadow logic circuitry coupled to the output circuitry and configured to perform combinatorial logic operations on data received from the output circuitry;
bypass circuitry configured to selectively bypass the memory array and provide test data directly to the shadow logic circuitry; and
self-timing circuitry configured to control timing of data propagation through the bypass circuitry using the same timing mechanisms used for normal memory operations.

19. The memory circuit of claim 18, further comprising:
a test circuit coupled to an output of the shadow logic circuitry and configured to verify that output from the shadow logic circuitry matches expected results for given test data.

20. The memory circuit of claim 18, wherein the bypass circuitry comprises:
multiplexers configured to selectively route either data from the memory array or test data to the shadow logic circuitry based on a bypass mode signal.
